(19) United States
(12) Patent Application Publication
(10) Pub. No.: US 2010/0046293 A1
(43) Pub. Date: Feb. 25, 2010

(54) MEMORY CELL BLOCK OF NONVOLATILE MEMORY DEVICE AND METHOD OF MANAGING SUPPLEMENTARY INFORMATION

(76) Inventor: Sam Kyu WON, Gyeonggi-do (KR)

Correspondence Address: IP & T Law Firm PLC, 7700 Little River Turnpike, Suite 207, Annandale, VA, 22003, US

(21) Appl. No.: 12/493,335

(22) Filed: Jun. 29, 2009

(30) Foreign Application Priority Data
Aug. 19, 2008 (KR) 10-2008-0080804

(51) Int. Cl. G11C 16/04; G11C 16/06

(52) U.S. Cl. 365/185.11; 365/185.2; 365/185.29

(57) ABSTRACT

A nonvolatile memory device of a nonvolatile memory device includes a memory cell unit comprising sets of memory cells, a first supplementary information repository comprising source-side dummy cells respectively connected between source select transistors and first memory cells of the sets of the memory cells, and a second supplementary information repository comprising drain-side dummy cells respectively connected between drain select transistors and second memory cells of the sets of the memory cells.

### CROSS-REFERENCES TO RELATED APPLICATIONS

Priority to Korean patent application number 10-2008-0080804 filed on Aug. 19, 2008, the entire disclosure of which is incorporated by reference herein, is claimed.

### BACKGROUND

One or more embodiments relate to the memory cell block of a nonvolatile memory device, which is capable of storing supplementary information, and a method of managing supplementary information using the same.

Recently, there has been an increasing demand for nonvolatile memory devices which can be electrically programmed and erased and do not require the refresh function of rewriting data at specific periods.

A nonvolatile memory cell enables electrical program/erase operations and performs the program and erase operations by varying a threshold voltage varying when electrons are migrated by a strong electric field applied to a thin oxide layer.

The nonvolatile memory device typically includes a memory cell array in which cells for storing data are arranged in a matrix form and a page buffer for writing data into specific cells of the memory cell array or reading data stored in specific cells thereof. The page buffer includes bit line pairs connected to specific memory cells, a register for temporarily storing data to be written into the memory cell array or reading the data of specific cells from the memory cell array and temporarily storing the read data, a sensing node for detecting the voltage level of a specific bit line or a specific register, and a bit line select unit for controlling whether to connect the specific bit line to the sensing node.

With respect to memory cell array structures of such a nonvolatile memory device, a memory cell array structure further including dummy cells has recently been used. That is, memory cells, used as dummy cells, are further connected to an end of source-side memory cells and an end of drain-side memory cells. The outermost memory cells are likely to be subject to program disturbance and are subject to comparatively poor program cycle and retention characteristics. The dummy cells are used to counter the program cycle and retention problems. If the dummy cells are used, however, the chip size tends to increase. Accordingly, the dummy cells are desired to be more efficiently used, including the prevention of program disturbance.

### BRIEF SUMMARY

One or more embodiments are directed towards the memory cell block of a nonvolatile memory device, which is capable of storing various parts of supplementary information in dummy cells, included in a memory cell array, in order to efficiently use the dummy cells. Furthermore, one or more embodiments are directed towards a method of managing supplementary information, which is capable of storing, erasing, updating, and reading supplementary information using the memory cell block.

One or more embodiments are directed to a memory cell block of a nonvolatile memory device, including a memory cell unit comprising a first memory cell group and a second memory cell group, a first supplementary information repository comprising source-side dummy cells respectively connected between source select transistors and the first memory cell group, and a second supplementary information repository comprising drain-side dummy cells respectively connected between drain select transistors and the second memory cell group.

One or more embodiments are directed to a method of storing supplementary information in a nonvolatile memory device, including storing supplementary information, which is collected through a test operation, in a control unit, inputting the supplementary information to a page buffer connected to a memory cell block, and programming the supplementary information, which is input to the page buffer, into a supplementary information repository included in the memory cell block.

One or more embodiments are directed to a method of erasing supplementary information in a nonvolatile memory device, including inputting an erase command for a memory cell block, reading supplementary information stored in a supplementary information repository included in the memory cell block, storing the supplementary information in a register, performing an erase operation on the memory cell block, inputting the stored supplementary information to a page buffer connected to the memory cell block, and programming the supplementary information, which is input to the page buffer, into the supplementary information repository of the memory cell block.

One or more embodiments are directed to a method of updating supplementary information in a nonvolatile memory device, including reading supplementary information stored in a supplementary information repository included in a memory cell block, storing the read supplementary information in a register, updating some of the stored supplementary information, performing an erase operation on the memory cell block, inputting the updated supplementary information to a page buffer connected to the memory cell block, and programming the updated supplementary information, input to the page buffer, into the supplementary information repository.

One or more embodiments are directed to a method of reading supplementary information in a nonvolatile memory device, including inputting a read command for a supplementary information repository included in a memory cell block, inputting a block address indicative of the memory cell block, inputting a supplementary information repository read confirmation command, performing a read operation on the supplementary information repository, and outputting supplementary information in response to a read enable signal.

### BRIEF DESCRIPTION OF THE DRAWINGS

FIG. 1 is a detailed diagram showing the memory cell array of a nonvolatile memory device according to an embodiment;

FIG. 2 is a detailed diagram showing the memory cell array of a nonvolatile memory device according to another embodiment;

FIG. 3 is a diagram of supplementary information stored in a supplementary information repository according to an embodiment;

FIG. 4 is a flowchart showing a method of storing supplementary information in the supplementary information repository of a nonvolatile memory device according to an embodiment;

FIG. 5 is a flowchart showing a method of erasing supplementary information stored in the supplementary information repository of the nonvolatile memory device according to an embodiment;

FIG. 6 is a flowchart showing a method of reading supplementary information stored in the supplementary information repository of the nonvolatile memory device according to an embodiment; and

FIG. 7 is a flowchart showing a method of reading supplementary information stored in the supplementary information repository of the nonvolatile memory device according to another embodiment.

### DESCRIPTION OF SPECIFIC EMBODIMENT

Hereinafter, the present disclosure will be described in detail in connection with one or more embodiments with reference to the accompanying drawings. The figures are provided to allow those having ordinary skill in the art to understand the scope of one or more embodiments of the disclosure.

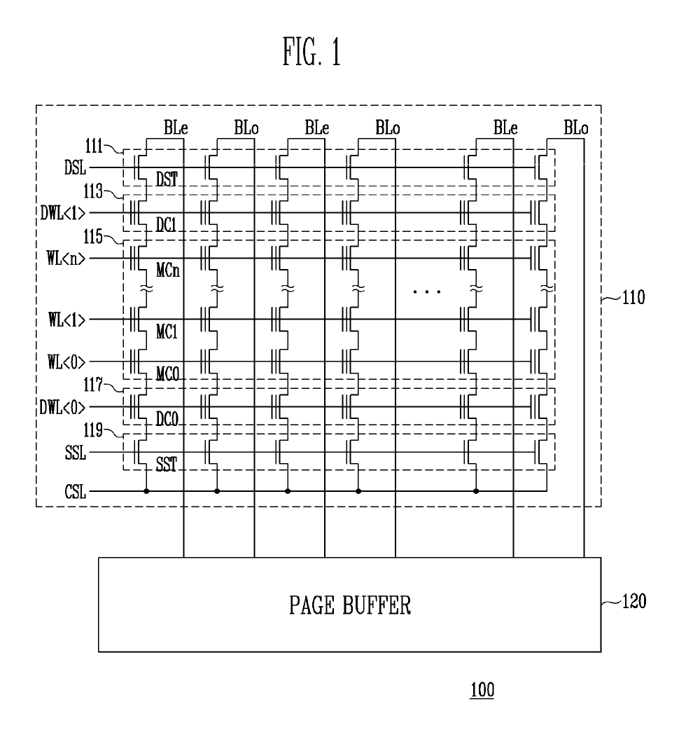

FIG. 1 is a detailed diagram showing the memory cell array of a nonvolatile memory device according to an embodiment.

The nonvolatile memory device 100 includes a memory cell array 110 and a page buffer 120.

The page buffer 120 has the same construction as those in a known nonvolatile memory device and, as such, a detailed description thereof is omitted.

The memory cell array 110 includes a memory cell unit 115, a drain select unit 111, a source select unit 119, a first supplementary information repository 117, and a second supplementary information repository 113. The memory cell unit 115 includes sets of memory cells MC0 to MCn configured to store data. The drain select unit 111 includes drain select transistors DST each configured to selectively connect a bit line and each of the sets of the memory cells MC0 to MCn. The source select unit 119 includes source select transistors SST each configured to selectively connect a common source line CSL and each of the sets of the memory cells MC0 to MCn. The first supplementary information repository 117 includes source-side dummy cells DC0 each connected between the memory cell MC0 and the source select transistor SST. The second supplementary information repository 113 includes drain-side dummy cells DC1 each connected between the memory cell MCn and the drain select transistor DST. Here, the memory cell array 110 forms one unit memory cell block. An erase operation is mainly performed on a memory-cell-block basis.

A program, read, erase operation or the like is performed on the memory cells MC0 to MCn depending on various high voltages applied thereto via word lines WL<0 to n>. Each of the drain select transistors DST selectively connects the bit line and the drain-side dummy cell DC1 depending on voltage applied thereto via a drain select line DSL. Each of the source select transistors SST selectively connects the common source line CSL and the source-side dummy cell DC0 depending on voltage applied thereto via the source select line SSL.

The first and second supplementary information repositories 117 and 113 are used to store various parts of supplementary information used in the operation of the nonvolatile memory device. The existing supplementary information repository protects data in such a manner that, after specific data is once recorded in an area of the repository, an erase operation is prevented from being performed on the data recorded on the area. This is sometimes called One Time Programmable (OTP) block. The OTP block is named as compared with a Multi-Time Programmable (MTP) block on which program and read operations can be performed several times. The supplementary information repository stores unique characteristic values, etc., which are obtained by testing corresponding characteristics, after the repository has been completed using a process of fabricating memory cells. The supplementary information repository further stores various parts of supplementary information indispensable for the operation of a nonvolatile memory device, such as information about a program pulse used for a program operation and an erase operation used for an erase pulse value, and repair information.

In one or more embodiments, the supplementary information repositories may be configured using the dummy cells each connected between the memory cell and the select transistor in order to prevent disturbance. The drain-side dummy cells DC1 and the source-side dummy cells DC0 are nonvolatile memory cells having the same characteristic as the memory cells MC0 to MCn. That is, the drain-side dummy cells DC1 and the source-side dummy cells DC0 have the same memory cell characteristic and experience a program operation, a read operation, or an erase operation. A program operation, a read operation, an erase operation, etc. are performed on the source-side dummy cells DC0 using a first dummy word line DWL<0>, and a program operation, a read operation, an erase operation, etc. are performed on the drain-side dummy cells DC1 using a second dummy word line DWL<1>.

In this case, the dummy cells require an operation for preventing an erase operation because they are erased when the erase operation is performed on the memory cells. This is described below in detail.

Meanwhile, according to one or more embodiments, only a Single Level Cell (SLC) program operation may be performed on the dummy cells, included in each of the supplementary information repositories, unlike in the memory cells. If a Multi-Level Cell (MLC) program operation is performed on the supplementary information repositories, the reliability of data may be relatively low because distribution-based read margin is narrow. For this reason, a supplementary information repository configured to store important supplementary information may store data using only the SLC program method.

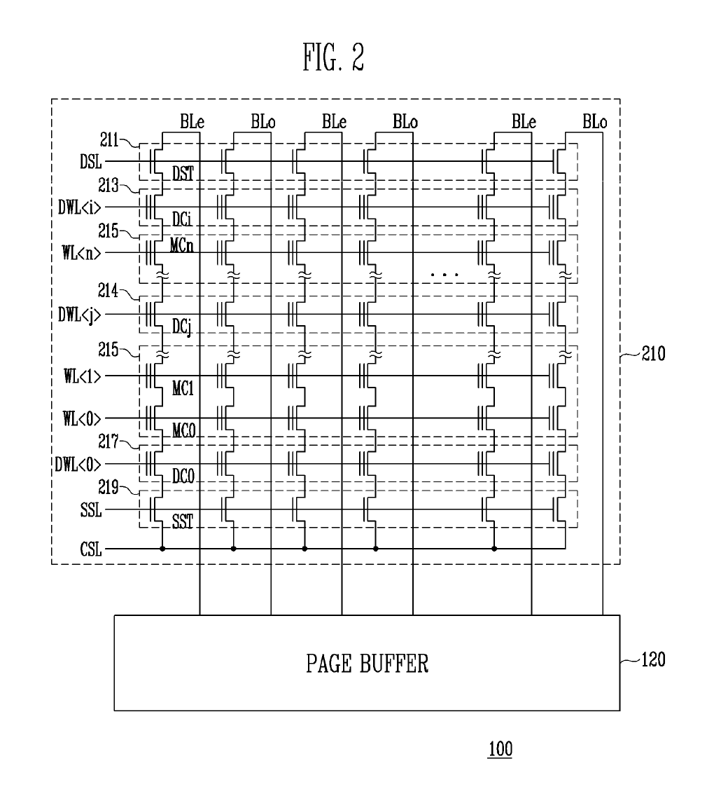

FIG. 2 is a detailed diagram showing the memory cell array of a nonvolatile memory device according to another embodiment.

The entire construction of the memory cell array shown in FIG. 2 is similar to that of the memory cell array shown in FIG. 1 except for the construction of supplementary information repositories.

The memory cell array 210 includes memory cell units 215, a drain select unit 211, a source select unit 219, a first supplementary information repository 217, a second supplementary information repository 213, and a third supplementary information repository 214. Each of the memory cell units 215 includes sets of memory cells MC0 to MCn configured to store data. The drain select unit 211 includes drain select transistors DST each configured to selectively connect a bit line and each of the sets of the memory cells MC0 to MCn. The source select unit 219 includes source select transistors SST each configured to selectively connect a common source line CSL and each of the sets of the memory cells MC0 to MCn. The first supplementary information repository 217 includes source-side dummy cells DC0 each connected between the memory cell MC0 and the source select transistor SST. The second supplementary information repository 213 includes drain-side dummy cells DCi each connected between the memory cell MCn and the drain select transistor DST. The third supplementary information repository 214 includes dummy cells DCj connected between the memory cell units 215.

Although it is illustrated that the one supplementary information repository 214 is included between the memory cell units 215, a number of the third supplementary information repositories 214 may be included according to one or more embodiments.

The remaining construction of the supplementary information repository other than the above description is the same as the supplementary information repository of FIG. 1.

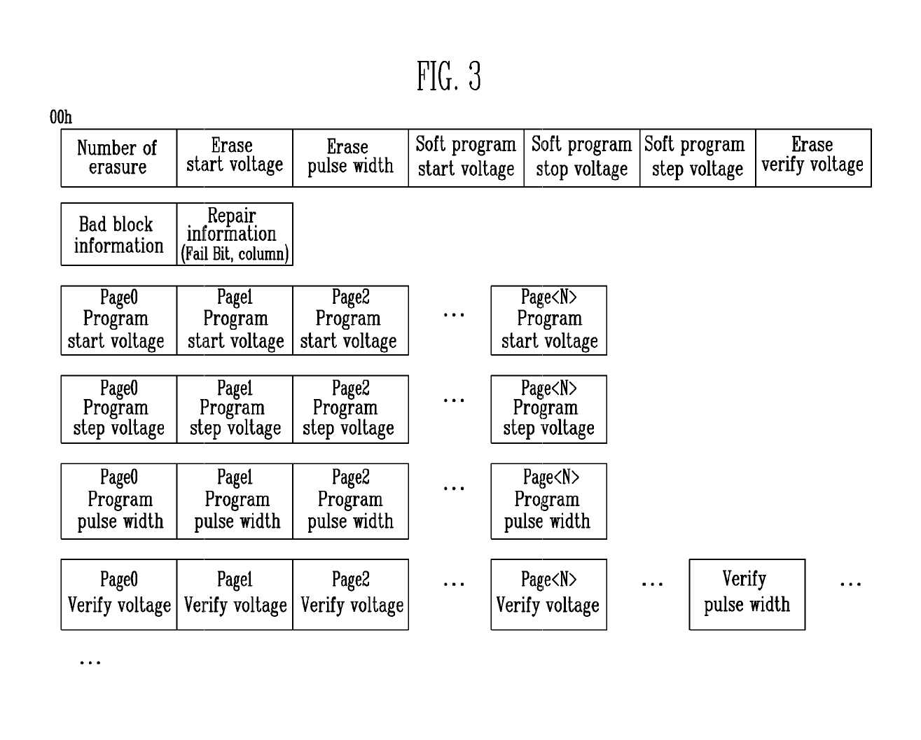

FIG. 3 is a diagram of supplementary information stored in the supplementary information repository according to an embodiment.

As shown in FIG. 3, in an erase operation using an Incremental Step Erase (ISPE) method, an erase start voltage, an erase pulse, etc. may be stored in the supplementary information repository. In a soft program operation performed in order to narrow distributions of erase cells after an erase operation, a soft program start voltage, a soft program stop voltage, a soft program step voltage, an ease verification voltage (HEV), and so on may be stored in the supplementary information repository. Information about bad blocks, repair information, etc. may also be stored in the supplementary information repository. In a program operation using an Incremental Step Pulse Program (ISPP) method, a program start voltage, a program step voltage, a program pulse width, and a verification voltage of each of pages within a memory cell block may be stored in the supplementary information repository.

Further, various parts of supplementary information used in the operation of a nonvolatile memory device, such as voltage control information used in a read operation and various parts of timing information, may be stored in the supplementary information repository. The storage capacity of each of the supplementary information repositories equals that of a single page and is configured to store various parts of supplementary information on the basis of the above storage capacity. For example, when the capacity of a single page is 2 KB, the capacity of a single supplementary information repository is also 2 KB and is therefore configured to store supplementary information on the basis of 2 KB.

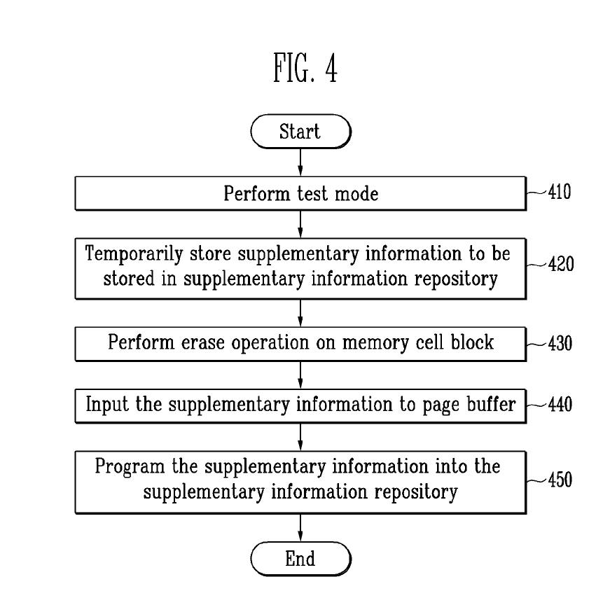

FIG. 4 is a flowchart showing a method of storing supplementary information in the supplementary information repository of a nonvolatile memory device according to an embodiment.

First, a test for the memory cells is performed at step 410. The test is performed in relation to the characteristics, failure, etc. of the memory cells in a wafer level, and the test results are supplementary information to be stored in the supplementary information repository.

The supplementary information to be stored in the supplementary information repository is then temporarily stored at step 420. Here, the supplementary information may be stored in the register of a control unit configured to control the operation of the nonvolatile memory device, etc

An erase operation is then performed on the memory cell block at step 430. For the erase operation, the supplementary information repository may be reset. The supplementary information repository is configured to include the dummy cells and is included within the memory cell block, so the supplementary information repository can become an erase state through the erase operation. Here, the erase operation is performed according to a known erase operation of a nonvolatile memory device and a description thereof is omitted.

Next, the supplementary information is input to the page buffer at step 440. The supplementary information is stored in the page buffer in the same manner as that external data is stored in a page buffer before being programmed into memory cells.

The supplementary information, stored in the page buffer, is then stored in the supplementary information repository through a program operation at step 450. Here, the supplementary information stored in the page buffer is programmed into the supplementary information repository in the same manner as that external data stored in a page buffer is programmed into memory cells. The supplementary information may be stored using an SLC program method. The supplementary information stored using the SLC program method may be performed according to any known program operation of a nonvolatile memory device and thus, a detailed description thereof is omitted.

The various parts of supplementary information collected in the test operation as described above are programmed and stored in the supplementary information repository.

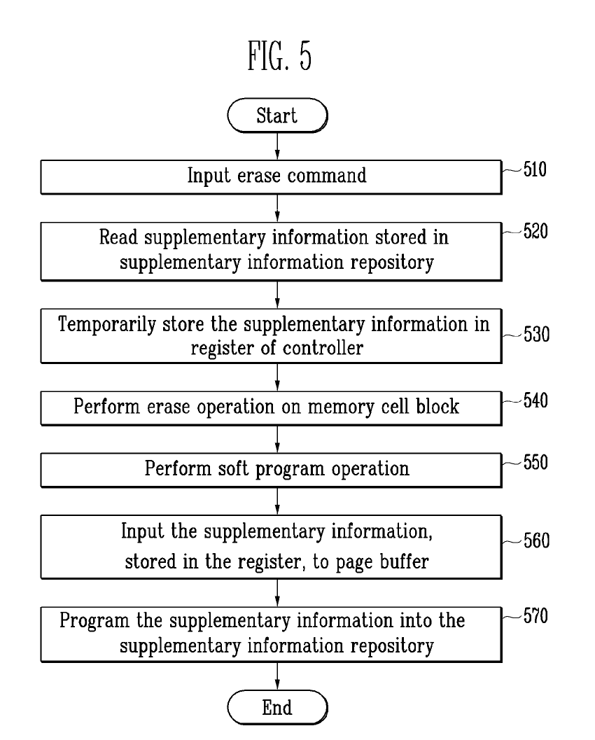

FIG. 5 is a flowchart showing a method of erasing supplementary information stored in the supplementary information repository of the nonvolatile memory device according to an embodiment.

When an erase command is input at step 510, supplementary information, stored in a supplementary information repository (i.e., the subject of erasure) included within the memory cell block, is read at step 520. The read operation is performed using a known read operation of a nonvolatile memory device. That is, the data of dummy cells within the supplementary information repository is read and then stored in the page buffer.

Next, the read supplementary information is temporarily stored in the register of the control unit at step 530. After an erase operation for the memory cell block has been performed, an erase verification operation, a soft program operation, a soft program verification operation, etc. are sequentially performed. Accordingly, a latch included in the page buffer is used in order to perform the verification operation. Accordingly, the supplementary information stored in the page buffer is output to the outside of the page buffer and is then temporarily stored in the register of the control unit.

An erase operation is then performed on the memory cell block at step 540.

Here, the erase operation is performed on all memory cells and all dummy cells, included in the memory cell block. Although not shown in this flowchart, an erase verification operation for checking whether the erase operation has been completed is further performed.

Next, a soft program operation is performed on the cells on which the erase operation has been performed at step 550. The soft program operation is performed in order to narrow the distributions of threshold voltages of the cells on which the erase operation has been performed. With the introduction of the MLC program operation, it is necessary to sufficiently secure distribution-based read margin between different states of the MLC. To this end, the soft program operation is performed on cells having an erase state so that the cells are closely distributed on the basis of 0V. Although not shown in this flowchart, a soft program verification operation for checking whether the soft program operation has been completed is performed.

The supplementary information stored in the register is then input to the page buffer at step 560. This step is performed in order to store the supplementary information in the supplementary information repository again after the erase operation has been completed. This may lead to a benefit, such as that the erase operation has been precluded. Meanwhile, the supplementary information stored in the register may be updated to new information through the operation of the control unit. Accordingly, the present embodiment may be applied to update supplementary information stored in a supplementary information repository.

The supplementary information stored in the page buffer is then stored in the supplementary information repository through a program operation at step 570. The supplementary information stored in the page buffer is programmed into the supplementary information repository in the same manner as that external data, stored in a page buffer, is programmed into memory cells. The supplementary information may be stored in the supplementary information repository using an SLC program method.

Although the erase operation has been performed on the memory cell block as described above, the supplementary information initially stored in the supplementary information repository may remain intact. Furthermore the supplementary information stored in the supplementary information repository may be updated using the erase operation.

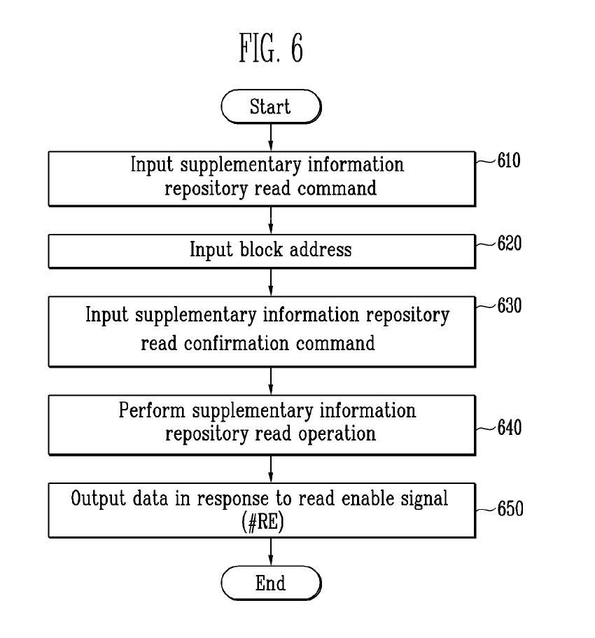

FIG. 6 is a flowchart showing a method of reading supplementary information stored in the supplementary information repository of the nonvolatile memory device according to an embodiment.

First, a supplementary information repository read command is input at step 610. A block address indicative of a memory cell block to be read is input at step 620. A read confirmation command for a supplementary information repository is then input at step 630.

Next, a read operation for the supplementary information repository is performed in response to the input of the confirmation command at step 640. The read operation is not performed on memory cells, but is performed on only a supplementary information repository included in the indicated memory cell block.

Supplementary information stored in the supplementary information repository is output according to a read enable signal # RE at step 650.

The supplementary information repository read command is a command created according to one or more embodiments. In the case where, during the operation of a nonvolatile memory device, supplementary information in a supplementary information repository is to be referred to, the read operation is performed on only the supplementary information repository.

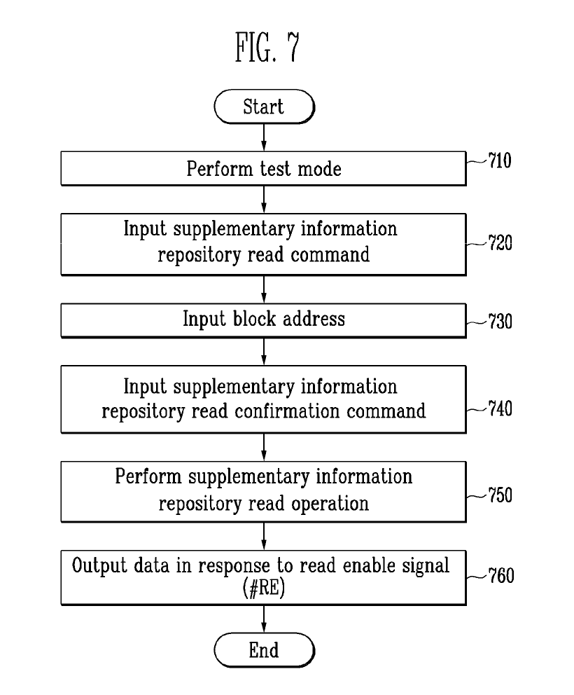

FIG. 7 is a flowchart showing a method of reading supplementary information stored in the supplementary information repository of the nonvolatile memory device according to another embodiment.

The method of FIG. 7 is almost the same as that of FIG. 6 except that, during a test mode, supplementary information stored in the supplementary information repository can be read.

As described above, various parts of supplementary information can be efficiently stored and managed using the dummy cells as the supplementary information repository. The supplementary information can be updated and stored according to a user selection because data can be stored in the supplementary information repository several times.

Furthermore, the dummy cells included in the nonvolatile memory device can be used as the supplementary information repository to store supplementary information and prevent disturbance. There is an advantage in that the supplementary information repository may function to update supplementary information because it can be erased and stored with data multiple times unlike the known supplementary information repositories.

What is claimed is:

1. A memory cell block of a nonvolatile memory device, comprising:
a memory cell unit comprising a first memory cell group and a second memory cell group;
a first supplementary information repository comprising source-side dummy cells respectively connected between source select transistors and the first memory cell group; and
a second supplementary information repository comprising drain-side dummy cells respectively connected between drain select transistors and the second memory cell group.

2. The memory cell block of claim 1, wherein the first and second supplementary information repositories are configured to store supplementary information about a characteristic of the nonvolatile memory device.

3. The memory cell block of claim 1, further comprising a third supplementary information repository connected between the first memory cell group and the second memory cell group.

4. The memory cell block of claim 3, wherein the third supplementary information repository is configured to store supplementary information about a characteristic of the nonvolatile memory device.

5. A memory cell block of a nonvolatile memory device, comprising:
a memory cell unit comprising a first memory cell group and a second memory cell group; and
a first supplementary information repository comprising source-side dummy cells respectively connected between source select transistors and the first memory cell group.

6. The memory cell block of claim 5, wherein the first second supplementary information repository is configured to store supplementary information about a characteristic of the nonvolatile memory device.

7. The memory cell block of claim 5, further comprising a third supplementary information repository connected between the first memory cell group and the second memory cell group.

8. The memory cell block of claim 7, wherein the third supplementary information repository is configured to store supplementary information about a characteristic of the nonvolatile memory device.

9. A memory cell block of a nonvolatile memory device, comprising:
a memory cell unit comprising a first memory cell group and a second memory cell group; and
a second supplementary information repository comprising drain-side dummy cells respectively connected between drain select transistors and the second memory cell group.

10. The memory cell block of claim 9, wherein the second supplementary information repository is configured to store supplementary information about a characteristic of the nonvolatile memory device.

11. The memory cell block of claim 9, further comprising a third supplementary information repository connected between the first memory cell group and the second memory cell group.

12. The memory cell block of claim 11, wherein the third supplementary information repository is configured to store supplementary information about a characteristic of the nonvolatile memory device.

13. A method of storing supplementary information in a nonvolatile memory device, the method comprising:
storing supplementary information, which is collected through a test operation in a control unit;
inputting the supplementary information to a page buffer connected to a memory cell block; and
programming the supplementary information, which is input to the page buffer, into a supplementary information repository included in the memory cell block.

14. The method of claim 13, further comprising, before the supplementary information is input to the page buffer connected to the memory cell block, performing an erase operation on the memory cell block.

15. The method of claim 14, wherein the execution of the erase operation comprises resetting dummy cells included in the supplementary information repository.

16. The method of claim 15, wherein the supplementary information repository comprises source-side dummy cells, which are respectively connected between first memory cells and source select transistors or drain-side dummy cells and are respectively connected between second memory cells and drain select transistors.

17. The method of claim 13, wherein the programming of the supplementary information comprises programming the supplementary information into dummy cells, which are included in the supplementary information repository, using a single level cell program method.

18. A method of erasing supplementary information in a nonvolatile memory device, the method comprising:
inputting an erase command for a memory cell block;
reading supplementary information stored in a supplementary information repository included in the memory cell block;
storing the supplementary information in a register;
performing an erase operation on the memory cell block;
inputting the stored supplementary information to a page buffer connected to the memory cell block; and
programming the supplementary information, which is input to the page buffer, into the supplementary information repository of the memory cell block.

19. The method of claim 18, further comprising, after the erase operation has been performed, performing a soft program operation on the memory cell block.

20. The method of claim 18, further comprising, before the stored supplementary information is input to the page buffer connected to the memory cell block, modifying some of the supplementary information stored in the register and storing the modified supplementary information in the register.

21. The method of claim 18, wherein the supplementary information repository comprises source-side dummy cells, which are respectively connected between first memory cells and source select transistors or drain-side dummy cells and are respectively connected between second memory cells and drain select transistors.

22. The method of claim 18, wherein the programming of the supplementary information comprises programming the supplementary information into dummy cells, which are included in the supplementary information repository, using a single level cell program method.

23. A method of updating supplementary information in a nonvolatile memory device, the method comprising:
reading supplementary information stored in a supplementary information repository included in a memory cell block;
storing the read supplementary information in a register;
updating some of the stored supplementary information;
performing an erase operation on the memory cell block;
inputting the updated supplementary information to a page buffer connected to the memory cell block; and
programming the updated supplementary information, input to the page buffer, into the supplementary information repository.

24. A method of reading supplementary information in a nonvolatile memory device, the method comprising:
inputting a read command for a supplementary information repository included in a memory cell block;
inputting a block address indicative of the memory cell block;
inputting a supplementary information repository read confirmation command;
performing a read operation on the supplementary information repository; and
outputting supplementary information in response to a read enable signal.

25. The method of claim 24, wherein the entire method is performed during a test mode.
